(19) United States
(12) Patent Application Publication
(10) Pub. No.: US 2026/0103477 A1
(43) Pub. Date: Apr. 16, 2026

(54) TRISILYLAMINE COMPOUND, COMPOSITION FOR DEPOSITING SILICON-CONTAINING THIN FILM INCLUDING THE SAME, AND METHOD OF MANUFACTURING SILICON-CONTAINING THIN FILM USING THE SAME

(71) Applicant: DNF CO., LTD., Daejeon (KR)

(72) Inventors: Se Jin JANG, Daejeon (KR); Jeong Joo PARK, Daejeon (KR); Eun Jin SHIN, Daejeon (KR); Joong Jin PARK, Daejeon (KR); Gun Joo PARK, Daejeon (KR); Sung Gi KIM, Daejeon (KR); In Kyung JUNG, Daejeon (KR); Samdong LEE, Daejeon (KR); Gyun Sang LEE, Daejeon (KR)

(21) Appl. No.: 19/044,394

(22) Filed: Feb. 3, 2025

(30) Foreign Application Priority Data
Oct. 14, 2024 (KR) 10-2024-0139401

(51) Int. Cl. C07F 7/10; C23C 16/34; C23C 16/455

(52) U.S. Cl. CPC C07F 7/10; C23C 16/345; C23C 16/45553

(57) ABSTRACT

Provided are a trisilylamine compound, a composition for depositing a silicon-containing thin film including the compound, and a method of manufacturing a silicon-containing thin film using the same, and since the silicon-containing thin film manufactured from the trisilylamine compound according to the present disclosure has both excellent chemical and thermal stability and has low permittivity, it may be usefully applied as an insulating film of a semiconductor device, in particular, a spacer of a semiconductor miniaturization process.

### CROSS-REFERENCE TO RELATED APPLICATIONS

This application claims priority under 35 U.S.C. § 119 to Korean Patent Application 10-2024-0139401, filed on Oct. 14, 2024, in the Korean Intellectual Property Office, the disclosure of which is incorporated herein by reference in its entirety for all purposes.

### TECHNICAL FIELD

The following disclosure relates to a trisilylamine compound which may be used as a precursor of a silicon thin film, a composition for depositing a silicon-containing thin film comprising the same, and a method of manufacturing a silicon-containing thin film using the same.

### BACKGROUND

Performance and reliability of a semiconductor device greatly depend on electrical and mechanical properties of various materials inside the device. In particular, an insulating film plays an important role in reducing signal interference and stabilizing electrical properties of the device in the semiconductor device. Therefore, various technologies for improving physical and chemical properties of an insulating film are being studied.

A silicon oxide film or a silicon nitride film which is mainly used as a conventional insulating film material provides excellent insulating properties, but as miniaturization of advanced devices proceeds, the need for new insulating materials requiring low permittivity is emerging. As the permittivity of the insulating film is lowered, device performance is improved and electrical interference (capacitance) occurring during signal transmission may be decreased. In order to respond to the requirements, a fluorine (F)-doped silicon thin film is attracting attention. Since fluorine has high electronegativity and may lower the permittivity of an insulating film when doped into a silicon thin film, it may greatly improve electrical performance of the device. In addition, fluorine doping decreases charge trapping of the insulating film to increase long-term reliability of the device and enhances resistance to moisture to play an important role in preventing performance degradation due to an external environment.

However, a precursor for forming a silicon thin film containing fluorine is still in the development stage, and a stable and efficient deposition process is required. A conventional precursor has limitations in forming a uniform thin film while stably maintaining a fluorine content, and a method of doping fluorine (F) after forming a silicon thin film has been suggested, but this additionally involves a fluorine doping step to complicate the process, and doping proceeds only near the surface of the thin film, so that there is a limit to deterioration of thin film quality.

Accordingly, development of a new precursor which may deposit a silicon thin film containing fluorine more effectively is needed.

### RELATED ART DOCUMENTS

### Patent Document

Korean Patent Laid-Open Publication No. 10-2014-0113128 (Apr. 27, 2020)

### SUMMARY

An embodiment of the present disclosure is directed to providing a trisilylamine compound which may be used as a high-quality and low-permittivity thin film precursor and a composition for depositing a silicon-containing thin film comprising the compound.

Another embodiment of the present disclosure is directed to providing a method of manufacturing a silicon-containing thin film, which allows manufacture of a silicon-containing thin film at a high deposition rate and manufacture a high-quality thin film with a high yield.

In one general aspect, a trisilylamine compound represented by the following Chemical Formula 1 is provided:

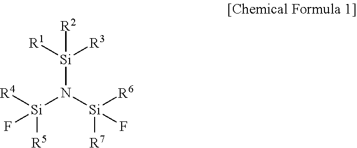

wherein
R¹ to R⁷ are independently of one another hydrogen, C1-C7 alkyl, or fluoro.
R¹, R⁴, and R⁶ may be independently of one another hydrogen or fluoro; and R³, R⁵, and R⁷ may be independently of one another hydrogen, C1-C7 alkyl, or fluoro.

The trisilylamine compound according to an embodiment may be represented by the following Chemical Formula 2:

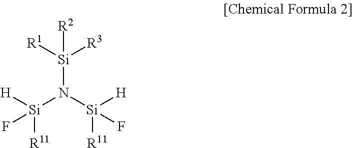

wherein
R¹ to R³ and R¹¹ are independently of one another hydrogen, C1-C7 alkyl, or fluoro.

R¹ may be hydrogen or fluoro; R² and R³ may be independently of each other hydrogen, C1-C7 alkyl, or fluoro; and R¹¹ may be C1-C7 alkyl or fluoro.

The trisilylamine compound according to an embodiment may be selected from the following structures:

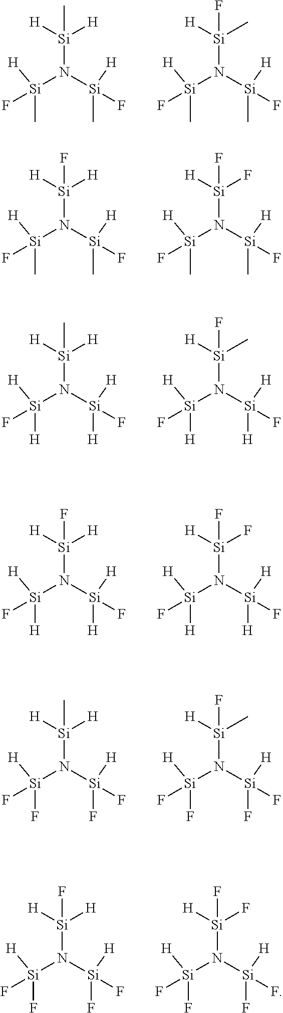

In another general aspect, a composition for depositing a silicon-containing thin film comprises the trisilylamine compound.

In another general aspect, a silicon-containing thin film manufactured from the trisilylamine compound represented by the following Chemical Formula 1 or a composition for depositing a thin film including the same is provided:

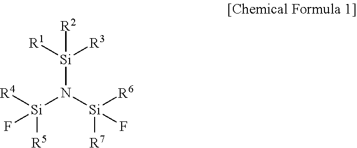

wherein
R¹ to R⁷ are independently of one another hydrogen, C1-C7 alkyl, or fluoro.

In still another general aspect, a method of manufacturing a silicon-containing thin film, which uses a trisilylamine compound represented by the following Chemical Formula 1 or a composition for depositing a thin film comprising the same; and a reaction gas, is provided:

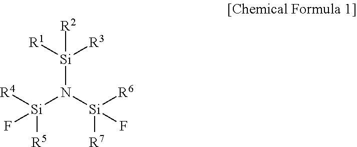

wherein
R¹ to R⁷ are independently of one another hydrogen, C1-C7 alkyl, or fluoro.

The reaction gas may include oxygen (O₂), ozone (O₃), oxygen plasma, hydrogen (H₂), hydrogen plasma, water (H₂O), hydrogen peroxide (H₂O₂), nitrogen (NO₂), nitrogen monoxide (NO), nitrous oxide (N₂O), ammonia (NH₃), carbon dioxide (CO₂), formic acid (HCOOH), acetic acid (CH₃COOH), anhydrous acetic acid ((CH₃CO)₂O), or a combination thereof.

The reaction gas may further comprise a hydrocarbon gas.

Other features and aspects will be apparent from the following detailed description, the drawings, and the claims.

### BRIEF DESCRIPTION OF THE DRAWINGS

FIG. 1 is the results of TGA and DSC analyses of bis(fluoromethylsilyl)methylsilylamine prepared in Example 1.

### DETAILED DESCRIPTION OF EMBODIMENTS

In the present specification, unless otherwise defined, all technical terms and scientific terms have the same meanings as those commonly understood by a person skilled in the art to which the present disclosure pertains. The terms used herein are only for effectively describing a certain specific example, and are not intended to limit the present disclosure.

The singular form used in the present specification may be intended to also include a plural form, unless otherwise indicated in the context.

Throughout the present specification, unless otherwise particularly stated, “comprising”, “being equipped with”, “containing”, or “having” a constituent element does not mean excluding any other constituent element, but mean further including other constituent elements, and elements, materials, or processes which are not further listed are not excluded.

The numerical range used in the present specification includes all values within the range including the lower limit and the upper limit, increments logically derived in a form and spanning in a defined range, all double limited values, and all possible combinations of the upper limit and the lower limit in the numerical range defined in different forms. Unless otherwise defined in the present specification, values which may be outside a numerical range due to experimental error or rounding off of a value are also included in the defined numerical range.

Unless otherwise particularly defined in the present specification, “about” may be considered as a value within 30%, 25%, 20%, 15%, 10%, or 5% of a stated value.

The term “alkyl” in the present specification is an organic radical derived from an aliphatic hydrocarbon by removal of one hydrogen, and may include both linear and branched alkyls. The alkyl may have 1 to 7, specifically 1 to 5, and more specifically 1 to 4 carbon atoms. The linear alkyl may include, as an example, methyl, ethyl, n-propyl, n-butyl, n-pentyl, n-hexyl, n-heptyl, and the branched alkyl may include isopropyl, sec-butyl, isobutyl, tert-butyl, isopentyl, 2-methylhexyl, 3-methylbutyl, 2-methylpentyl, 3-methylpentyl, 4-methylpentyl, 2-methylhexyl, 3-methylhexyl, 2-methylpentyl, 3-methylpentyl, 4-methylpentyl, 2-methylhexyl, 3-methylhexyl, 4-methylhexyl, 5-methylhexyl, 2,3-dimethylbutyl, 2,3-dimethylpentyl, 2,4-dimethylpentyl, and the like, but they are not limited thereto.

Hereinafter, the present disclosure will be described in detail. However, it is only illustrative and the present disclosure is not limited to the specific exemplary embodiment which is illustratively described.

An embodiment of the present disclosure provides a trisilylamine compound useful as a precursor of a high-quality silicon thin film. Specifically, the trisilylamine compound according to an embodiment may be represented by the following Chemical Formula 1:

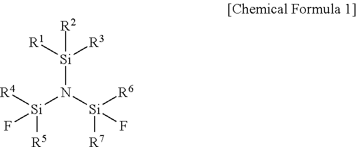

wherein
R¹ to R⁷ are independently of one another hydrogen, C1-C7 alkyl, or fluoro.

Since the trisilylamine compound has the structural characteristic described above, for example, a trisilylamine compound having a structure in which three silyl groups are substituted includes at least two silyl groups including at least one fluoro (—F) group, a high-purity silicon-containing thin film may be easily formed with a high deposition rate. In addition, since a silicon-containing thin film manufactured from the trisilylamine compound according to an embodiment may further contain fluorine (F) and has lower permittivity, it is expected to be useful as an insulating film material of a semiconductor device.

As an example, R¹, R⁴, and R⁶ may be independently of one another hydrogen or fluoro; and R², R³, R⁵, and R⁷ may be independently of one another hydrogen, C1-C7 alkyl or fluoro, specifically, hydrogen, C1-C4 alkyl, or fluoro, or hydrogen, methyl, or fluoro.

As an example, the trisilylamine compound may be represented by the following Chemical Formula 2:

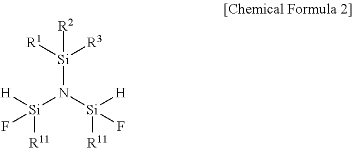

wherein
R¹ to R³ and R¹¹ are independently of one another hydrogen, C1-C7 alkyl, or fluoro.

As an example, R¹ may be hydrogen or fluoro; R² and R³ may be independently of each other hydrogen, C1-C7 alkyl, or fluoro; and R¹¹ may be C1-C7 alkyl or fluoro.

As an example, R² and R³ may be independently of each other hydrogen, C1-C4 alkyl, or fluoro, specifically, hydrogen, C1-C4 alkyl, or fluoro, or hydrogen, methyl, or fluoro.

As an example, R^{II} may be C1-C4 alkyl or fluoro, or methyl or fluoro.

The trisilylamine compound may be selected from the following structures, but is not limited thereto:

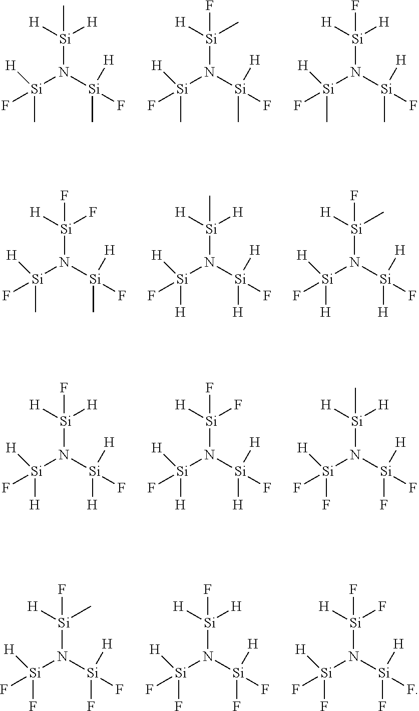

Hereinafter, the method for preparing the trisilylamine compound represented by Chemical Formula 1 will be described in detail, but the trisilylamine compound may be synthesized also by a method which may be recognized by a person skilled in the art, of course, an organic solvent used herein is not limited, and a reaction time and temperature may be also changed within a range which does not depart from the gist of the disclosure, of course.

The trisilylamine compound represented by Chemical Formula 1 according to an embodiment may be prepared by including (A) reacting a compound represented by the following Chemical Formula 21 and a chloride source to prepare a compound represented by the following Chemical Formula 22; and (B) reacting the compound represented by the following Chemical Formula 22 and a fluoride source to prepare a trisilylamine compound of Chemical formula 1:

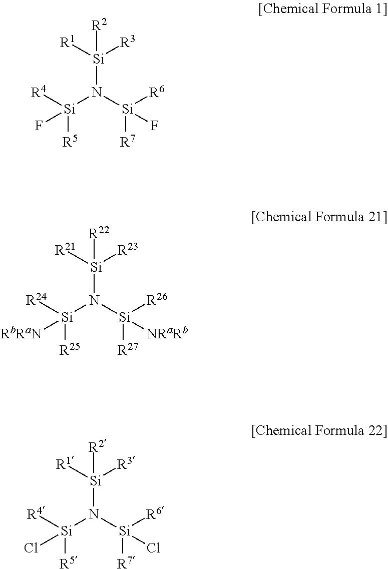

wherein
R²¹ to R²⁷ are independently of one another hydrogen, C1-C7 alkyl, or NR^{a}R^{b};

R^{1′} to R^{7′} are independently of one another hydrogen, C1-C7 alkyl, or chloro (Cl);

R¹ to R⁷ are independently of one another hydrogen, C1-C7 alkyl, or fluoro (F); and

Ra and R^{b} are independently of each other C1-C7 alkyl.

The step (A) is a reaction to substitute —NR^{a}R^{b} of the compound represented by Chemical Formula 21 with —Cl, and may be performed at 20 to 50° C. for 1 hour to 10 hours, specifically 20 to 30° C. for 1 to 5 hours, but is not limited thereto, and may be changed depending on the reaction material, the type of solvent, and the amount of use.

The chloride source may be selected from hydrogen chloride (HCl), acetyl chloride (CH₃COCl), thionyl chloride (SOCl₂), silicon tetrachloride (SiCl₄), dichlorophenylphosphine (C₆HSCl₂P), and the like, but is not limited thereto.

The step (B) may be a step of substituting —Cl of the compound represented by Chemical Formula 22 with —F using the fluoride source, and the fluoride source may be alkali metal fluorides such as LiF, KF, NaF, RbF, and CsF, or transition metal fluorides such as AgF, AgF₂, ZnF₂, CuF₂, CuF₂·H₂O, NiF₂, SnF₂, InF₃, ScF₃, TiF₃, MnF₃, CoF₃, CrF₃, AuF₃, FeF₃, MnF₃, BiF₃, and SbF₃, but is not limited thereto.

The reaction of step (B) may be performed at 20 to 50° C. for 1 hour to 10 hours, specifically 20 to 40° C. for 1 to 8 hours, but is not limited thereto, and may be changed depending on the reaction material, the type of solvent, and the amount of use.

The trisilylamine compound represented by Chemical Formula 1 according to an embodiment may be prepared by reacting a compound represented by the following Chemical Formula 31 and a compound represented by the following Chemical Formula 32:

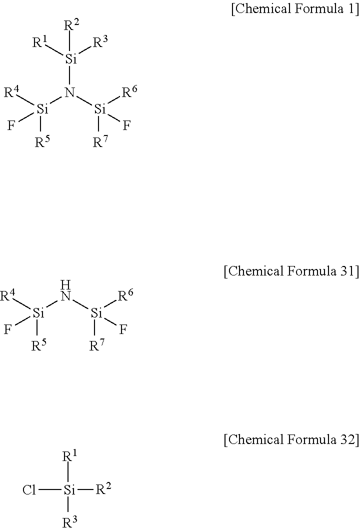

wherein
R¹ to R⁷ are independently of one another hydrogen, C1-C7 alkyl, or fluoro.

The reaction of the compound represented by Chemical Formula 31 and the compound represented by Chemical Formula 32 may be performed in the presence of a base catalyst selected from NaH, KH, n-BuLi, LiH, and the like, and may be performed at 20 to 50° C. for 1 hour to 10 hours, specifically at 20 to 40° C. for 1 hour to 8 hours, but is not limited thereto, and may be changed depending on the reaction material, the type of solvent, and the amount of use.

The compound represented by Chemical Formula 31 may be prepared by including (a) reacting a compound represented by the following Chemical Formula 33 and compounds represented by Chemical Formulae 34 and 35 to prepare a compound represented by the following Chemical Formula 36; and (b) reacting the compound represented by the following Chemical Formula 36 and a fluoride source to prepare the compound represented by the following Chemical Formula 31:

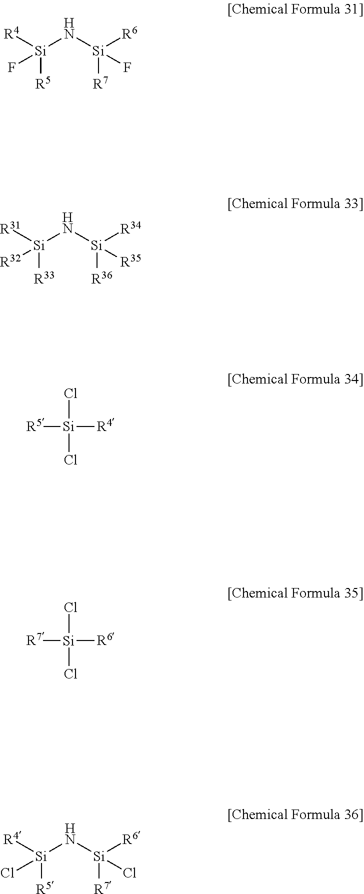

wherein
R^{4′} to R^{7′} are independently of one another hydrogen, C1-C7 alkyl, or chloro (Cl);

R⁴ to R⁷ are independently of one another hydrogen, C1-C7 alkyl, or fluoro (F); and

R³¹ to R³⁶ are independently of one another C1-C7 alkyl.

As an example, R³¹ to R³⁶ may be independently of one another C1-C7 alkyl, C1-C4 alkyl, or methyl.

As an example, the compounds of Chemical Formulae 34 and 35 may be the same, or R³¹ to R³⁶ are the same and may be C1-C7 alkyl, C1-C4 alkyl, or methyl.

The step (a) may be performed at 50 to 200° C. for 5 hours to 20 hours, specifically at 80 to 120° C. for 5 to 10 hours, but may be changed depending on the reaction material, the type of solvent, and the amount of use, and may be performed until the by-products represented by the following Chemical Formulae 40 and 41 produced by the reaction are not recovered:

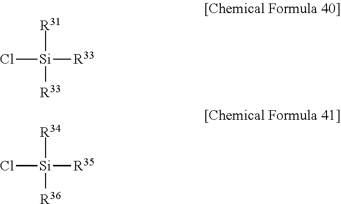

wherein R³¹ to R³⁶ are as defined above.

The step (b) may be a step of substituting —Cl of the compound represented by Chemical Formula 36 with —F using a fluoride source, and the fluoride source may be selected from alkali metal fluorides such as LiF, KF, NaF, RbF, and CsF, or transition metal fluorides such as AgF, AgF₂, ZnF₂, CuF₂, CuF₂·H₂O, NiF₂, SnF₂, InF₃, ScF₃, TiF₃, MnF₃, CoF₃, CrF₃, AuF₃, FeF₃, MnF₃, BiF₃, and SbF₃, but is not limited thereto.

The step (b) may be performed at 50 to 200° C. for 1 hour to 10 hours, specifically at 50 to 100° C. for 5 hours to 10 hours, but is not limited thereto, and may be changed depending on the reaction material, the type of solvent, and the amount of use.

In addition, an embodiment of the present disclosure provides a composition for depositing a silicon-containing thin film including the trisilylamine compound. The composition for depositing a silicon-containing thin film according to an embodiment (hereinafter, composition for depositing a thin film) necessarily includes the trisilylamine compound represented by Chemical Formula 1 as a precursor for depositing a thin film, and the content of the compound represented by Chemical Formula 1 in the composition may be within a range which may be recognized by a person skilled in the art considering the film forming conditions of the thin film, the thickness of the thin film, the characteristics of the thin film, the use of the thin film, and the like.

Preferably, the composition for depositing a silicon-containing thin film according to an embodiment may be a composition for depositing a fluorine and silicon-containing thin film, and since a thin film prepared therefrom has low permittivity, it may be used as an insulating film material of a semiconductor device, and also, the thin film may be used as a deposition inhibition layer material, in which the trisilylamine compound according to an embodiment serves as an inhibitor.

Another embodiment of the present disclosure provides a method of manufacturing a silicon-containing thin film including depositing a silicon-containing thin film, which uses the trisilylamine compound represented by the following Chemical Formula 1 or a composition for depositing a thin film comprising the compound; and a reaction gas.

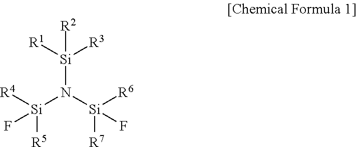

wherein
R¹ to R⁷ are independently of one another hydrogen, fluoro, or C1-C7 alkyl.

Since the method of manufacturing a silicon-containing thin film according to an embodiment uses the trisilylamine compound represented by Chemical Formula 1 as a precursor, a high-quality silicon-containing thin film may be manufactured with a high deposition rate, and preferably, a fluorine and silicon-containing thin film may be manufactured.

Specifically, the method of manufacturing a silicon-containing thin film according to an embodiment has a benefit of manufacturing a thin film containing both fluorine and silicon with one precursor, by leaving fluorine (F) of the trisilylamine compound represented by Chemical Formula 1 in the thin film. That is, generally, a fluorine and silicon-containing thin film is obtained by manufacturing a silicon-containing thin film and then doping fluorine using a fluorine-containing precursor, but in this case, a fluorine content in the thin film may be non-uniform. However, the method of manufacturing a fluorine and silicon-containing thin film of the present disclosure may overcome the disadvantage to manufacture a fluorine and silicon-containing thin film having a uniform fluorine content from one precursor.

The deposition method is not particularly limited as long as it is commonly used in the art, but, for example, atomic layer deposition (ALD), chemical vapor deposition (CVD), metal organic chemical vapor deposition (MOCVD), low pressure chemical vapor deposition (LPCVD), plasma enhanced chemical vapor deposition (PECVD), or plasma enhanced atomic layer deposition (PEALD) may be used, but the present disclosure is not limited thereto.

In the method of manufacturing a silicon-containing thin film according to an embodiment, the trisilylamine compound and the reaction gas may be supplied continuously or discontinuously, and the discontinuous supply may include a pulse form.

As an example, the method of manufacturing a silicon-containing thin film may include: a) maintaining a temperature of a substrate mounted in a chamber at 100° C. or higher; b) adsorbing the trisilylamine compound represented by Chemical Formula 1 or the composition for depositing a thin film including the compound onto a substrate; and c) injecting a reaction gas into the substrate onto which the trisilylamine compound or the composition for depositing a thin film is adsorbed to deposit the silicon-containing thin film thereon.

Specifically, the method of manufacturing a silicon-containing thin film may include: a) maintaining a temperature of a substrate mounted in a chamber at 100° C. or higher; b) adsorbing the trisilylamine compound represented by Chemical Formula 1 or the composition for depositing a thin film including the compound onto a substrate; c) purging a residual trisilylamine compound or a residual composition for deposition and by-products; d) injecting a reaction gas into the substrate onto which the trisilylamine compound or the composition for depositing a thin film is adsorbed to form a silicon-containing thin film; and e) purging a residual reaction gas and by-products.

The type of reaction gas is not particularly limited as long as it is commonly used in the art, but may be selected from oxygen (O₂), ozone (O₃), oxygen plasma, hydrogen (H₂), hydrogen plasma, water (H₂O), hydrogen peroxide (H₂O₂), nitrogen (NO₂), nitrogen monoxide (NO), nitrous oxide (N₂O), ammonia (NH₃), carbon dioxide (CO₂), formic acid (HCOOH), acetic acid (CH₃COOH), anhydrous acetic acid ((CH₃CO)₂O), or a combination thereof.

In addition, the reaction gas may further include a hydrocarbon gas, and the hydrocarbon gas may be C2-C12 alkene, C2-C10 alkene, or C2-C6 alkene gas, and as an example, may be selected from 1-hexene, propylene, and acetylene, and the hydrocarbon gas may be injected using inert gas as a transfer gas.

Though the substrate is not particularly limited as long as it is commonly used in the art, it may be, for example, a substrate including one or more semiconductor materials among Si, Ge, SiGe, GaP, GaAs, SiC, SiGeC, InAs, and InP; a silicon on insulator (SOI) substrate; a quartz substrate; a glass substrate for display; or a flexible plastic substrate such as polyimide (PI), polyethylene terephthalate (PET), polyethylene naphthalate (PEN), polymethyl methacrylate (PMMA), polycarbonate (PC), polyethersulfone (PES), and polyester.

In addition, the silicon-containing thin film may be formed directly on the substrate, but also, a plurality of conductive layers, dielectric layers, insulating layers, or the like may be further formed between the substrate and the silicon-containing thin film.

As an example, the temperature of the substrate may be 100 to 800° C., 300 to 800° C., or 400 to 700° C., but is not limited thereto.

In addition, an embodiment of the present disclosure provides a silicon-containing thin film manufactured from the manufacturing method.

The silicon-containing thin film according to an embodiment may be any thin film which may be manufactured using the trisilylamine compound represented by Chemical Formula 1 within a range recognized by a person skilled in the art, and specifically, may be a silicon oxide film, a silicon nitride film, a silicon carbonitride film, a silicon carbide film, a fluorinated silicon carbide film, a fluorinated silicon oxide film, a silicon fluoride film, a fluorinated silicon nitride film, and the like, and additionally, various high-quality thin films containing silicon or fluorine and silicon within a range recognized by a person skilled in the art may be manufactured.

Since the silicon-containing thin film has very low permittivity as well as both excellent chemical and thermal stability, it may be used for various uses, for example, an insulating film, a diffusion barrier, a spacer, an intermetallic dielectric material, a protective layer, and the like in the manufacture of an electronic device. In addition, the silicon-containing thin film according to an embodiment may be used as a deposition inhibition layer, and the trisilylamine compound according to an embodiment may serve as an inhibitor.

Hereinafter, the exemplary embodiments described above will be described in detail through the following examples. However, the following examples are only for description, and do not limit the right scope.

### <Synthesis of Trisilylamine Compound>

### [Example 11] Synthesis of bis(fluoromethylsilyl)methylsilylamine

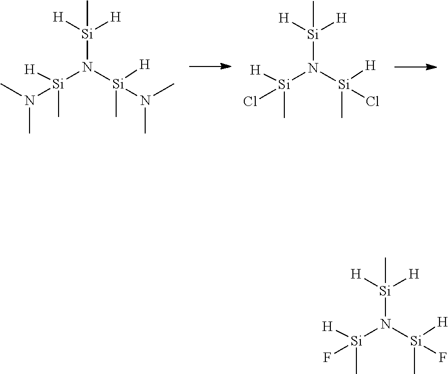

A reflux device was installed in a flame-dried 5 L flask under an anhydrous and inert atmosphere, 800 g (3.40 mol) of (bis((dimethyl)aminomethylsilyl)methylsilylamine) and 2500 g (34.02 mol) of pentane were added, cooling to −30° C. was performed, and 521 g (14.29 mol) of hydrogen chloride gas was slowly added while maintaining at or below −20° C. After the addition was completed, the temperature was slowly added to room temperature, and stirring was performed for about 3 hours to complete the reaction. The reaction mixture was distilled under reduced pressure under the conditions of 60° C. and 14 torr to recover 520 g of bis(chloromethylsilyl)methylsilylamine (yield: 70%, 2.38 mol).

639 g (3.57 mol) of antimony trifluoride (SbF₃) and 678 g (4.76 mol) of n-decane were added to a flame-dried 2 L flask under an anhydrous and inert atmosphere, and 520 g (2.38 mol) of bis(chloromethylsilyl)methylsilylamine prepared above was slowly added at room temperature. During the addition, the internal temperature was maintained at or below 35° C. After the addition was completed, stirring was performed for about 6 hours while maintaining at 35° C. to complete the reaction. After filtering the reaction mixture, the filtrate was distilled under reduced pressure under the conditions of 35° C. and 40 torr to obtain 309 g (1.67 mol) of bis(fluoromethylsilyl)methylsilylamine (yield: 70%, GC purity: 99%) as a target compound.

¹H-NMR (C₆D₆): 0.10 ppm (t, 3H, H2-Si—CH3), 0.14 ppm (m, 6H, F—Si—CH3), 4.53 ppm (m, 2H, CH3—Si—H2), 4.80˜4.96 ppm (dd, 2H, F—Si—H)

²⁹Si-NMR (CDCl₃): −27.6 ppm (d, Si, H2—Si), −8.4˜−4.8 ppm (dd, 2Si, Si—F)

### [Example 2] Synthesis of bis(fluoromethylsilyl)methylsilylamine

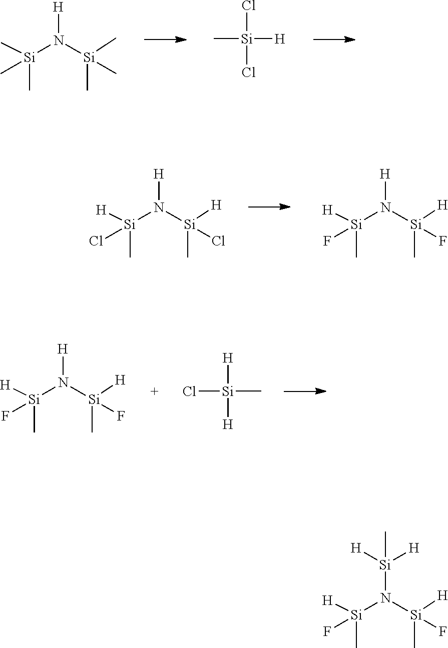

A Dean Stark reflux device was installed in a flame-dried 2 L flask under an anhydrous and inert atmosphere, 300 g (1.86 mol) of hexamethyldisilazane and 855 g (3.26 mol) of dichloromethylsilane were added thereto, heating to 80 to 120° C. was performed, and chlorotrimethylsilane as a produced by-product and excessively added dichloromethylsilane were recovered. Heating and stirring were performed for about 7-8 hours until chlormtrimethylsilane was not produced any more and not recovered. After the reaction mixture was slowly cooled to room temperature, distillation under reduced pressure was performed under the conditions of 40° C. and 0.5 torr to recover 291 g of 1,3-dichloro-1,3-dimethyldisilazane (yield: 90%, 1.67 mol) from the reaction mixture.

449 g (2.51 mol) of SbF₃ and 449 g (3.35 mol) of diethyleneglycoldimethylether (DEGDME) were added to a flame-dried 2 L flask under an anhydrous and inert atmosphere, and 291 g (1.67 mol) of 1,3-dichloro-1,3-dimethyldisilazane prepared above was slowly added thereto at room temperature. During the addition, the internal temperature was maintained at or below 40° C. After the addition was completed, stirring was performed at 70° C. for 8 hours and then filtration was performed. The obtained filtrate was distilled under reduced pressure under the conditions of 45° C. and 10 torr to recover 165 g of 1,3-difluoro-1,3-dimethyldisilazane (yield: 75%, 1.17 mol).

165 g (1.17 mol) of 1,3-difluoro-1,3-dimethyldisilazane prepared above and 606 g (7.03 mol) of n-hexane were added to a flame-dried 1 L flask under an anhydrous and inert atmosphere, and cooling to −40 to −30° C. was performed. 2.5 M n-BuLi hexane solution was slowly added dropwise while maintaining the internal temperature at or below −30° C. 94 g (1.17 mol) of chloromethylsilane was slowly added dropwise while maintaining the internal temperature at or below −30° C. The temperature was slowly raised to room temperature, stirring was performed at room temperature for 6 hours, and then filtration was performed. Hexane was removed by simply distillation from the obtained filtrate under the conditions of 80-90° C. and 760 torr, and distillation under reduced pressure was performed under the conditions of reduced pressure of 35° C. at 40 torr to obtain 50 g (0.35 mol) of bis(fluoromethylsilyl)methylsilylamine (yield: 30%, GC purity: 98%) as a target compound.

¹H-NMR (C₆D₆): 0.10 ppm (t, 3H, H2—Si—CH3), 0.14 ppm (m, 6H, F—Si—CH3), 4.53 ppm (m, 2H, CH3—Si—H2), 4.80˜4.96 ppm (dd, 2H, F—Si—H)

²⁹Si-NMR (CDCl₃): −27.6 ppm (d, Si, H2—Si), −8.4˜−4.8 ppm (dd, 2Si, Si—F)

### [Example 3] Synthesis of tri(fluoromethylsilyl)amine

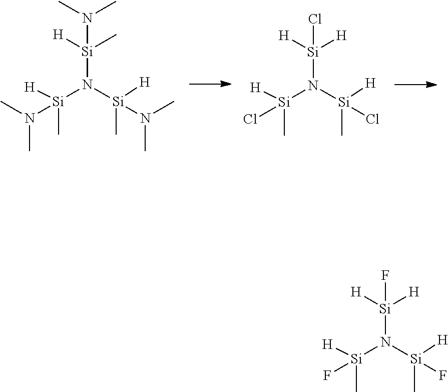

A reflux device was installed in a flame-dried 5 L flask under an anhydrous and inert atmosphere, 500 g (1.79 mol) of tri((dimethyl)aminomethylsilyl)amine and 1295 g (17.95 mol) of pentane were added, cooling to −30° C. was performed, and 275 g (7.54 mol) of hydrogen chloride gas was slowly added while maintaining at or below −20° C. After the addition was completed, the temperature was slowly added to room temperature, and stirring was performed for about 3 hours to complete the reaction. 392 g of tri(chloromethylsilyl)amine (yield: 70%, 1.26 mol) was recovered from the reaction mixture under the conditions of 65° C. and 14 torr.

337 g (1.88 mol) of SbF₃ and 357 g (2.51 mol) of n-decane were added to a flame-dried 2 L flask under an anhydrous and inert atmosphere, and 392 g (1.26 mol) of tri(chloromethylsilyl) prepared above was slowly added at room temperature. During the addition, the internal temperature was maintained at or below 35° C. After the addition was completed, stirring was performed for about 6 hours while maintaining at or below 35° C. to complete the reaction. After the reaction mixture was filtered, the filtrate was distilled under the conditions of 35° C. and 40 torr to obtain 163 g (0.88 mol) of tri(fluoromethylsilyl)amine (yield: 70%, GC purity: 98%) as a target compound.

¹H-NMR (C₆D₆): 0.15 ppm (m, 9H, F—Si—CH3), 5.0 ppm (m, 3H, F—Si—H)

²⁹Si-NMR (CDCl₃): —6.5 ppm (d, 2Si, Si—F)

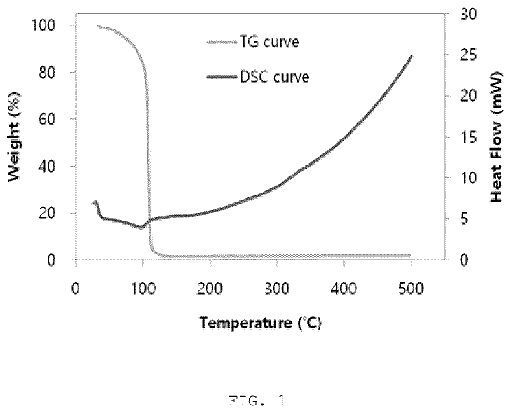

FIG. 1 shows the results of thermogravimetric analysis (TGA, L81-II, LINSEIS) and differential scanning calorimeter (DSC) analyses of bis(fluoromethylsilyl)methylsilylamine prepared in Example 1.

Referring to FIG. 1, it was found that the compound of Example 1 had a single evaporation step at about 100° C., residue mass was very low so that a rapid vaporization characteristic was shown, and almost all compound vaporized without thermal decomposition. In addition, it was found from the DSC graph that the compound of Example 1 had very good thermal stability.

### <Thin Film Deposition>

### [Example 4] Thermal Atomic Layer Deposition (TALD)

A silicon-containing thin film was manufactured in a common thermal atomic layer deposition (TALD) device using atomic layer deposition (ALD). Bis(fluoromethylsilyl)methylsilylamine prepared in Example 1 was used as a precursor, oxygen, hydrogen, and 1-hexene were used as a reaction gas, and argon was used as a purge gas.

A silicon substrate was set to the condition of 630° C., and as shown in the following Table 1, the precursor was maintained at −1 to 24° C. after being filled into a stainless steel bubbler container, and 1-hexene was maintained at −20° C. after being filled into a stainless steel bubbler container. First, the precursor vaporized in the stainless-steel bubbler container was transferred to a silicon substrate for 1 to 20 seconds using 100 sccm of argon gas as a transfer gas and adsorbed onto the silicon substrate. Second, an unadsorbed precursor was removed for about 10 to 20 seconds using 1,000-3,000 sccm of argon gas; third, as a reaction gas, 2,000 sccm of oxygen for 10 seconds or 1-hexene using 100 sccm of argon gas as a transfer gas for 20 seconds and 2,000 sccm of oxygen for 10 seconds, or 500 to 2,000 sccm of oxygen and 100 sccm of hydrogen for 3 seconds, or 1-hexene using 100 sccm of argon gas as a transfer gas for 5 to 20 seconds, 1,000 to 2,000 sccm of oxygen, and 20 to 1,000 sccm of hydrogen were flowed for 1 to 3 seconds to form a thin film; and finally, 1,000 to 3,000 sccm of argon gas was used to remove reaction by-products and residual reaction gas for 10 to 20 seconds. The above-described process was 1 cycle, and a set of cycles was repeated to form a thin film.

The thin film deposition conditions are shown in the following Table 1, and the detailed thin film deposition conditions, deposition results depending on the deposition conditions, the thickness of the deposited thin film, refractive index (R.I.), and density were measured and are shown in the following Table 2.

The thickness and the refractive index (R.I.) of the deposited thin film were measured using an ellipsometer (OPTI-PROBE 2600, THERMA-WAVE).

TABLE 1

| | | Bis(fluoromethylsilyl) | |
|---|---|---|---|
| Precursor | | methylsilylamine | |
| Deposition | | Atomic layer deposition (ALD) | |
| Substrate temperature (° C.) | | 630 | |
| Precursor | Heating temperature | −1-24 | |
| | (° C.) | | |
| | Injection time (sec) | 1-20 | |
| | Transfer gas (sccm) | 100 | |
| Purge gas | Flow rate (sccm) | 1000-3000 | |
| | Time (sec) | 10-20 | |
| Reaction gas | Oxygen flow rate (sccm) | 500-2000 | |
| | Hydrogen flow rate | 20-1000 | |
| | (sccm) | | |
| | Injection time (sec) | 1-10 | |
| 1-Hexene | Heating temperature | −20° | C. |
| | (° C.) | | |
| | Injection time (sec) | 5-20 | sec |
| | Transfer gas (Ar) | 100 | sccm |

| | | |
|---|---|---|
| Purge gas | Flow rate (sccm) | 1000-3000 |
| | Time (sec) | 10-20 |
| Number of | Cycle | 100-400 |
| deposition | | |

TABLE 2

| | | | | | Reaction | | | | | |
|---|---|---|---|---|---|---|---|---|---|---|
| | | | Oxygen | Hydrogen | gas | 1-Hexene | | | | |
| | Precursor | | flow | flow | injection | injection | Film | Growth | | |
| | Temperature | Injection | rate | rate | time | time | thickness | rate | | Density |
| Deposition | (° C.) | time (sec) | (sccm) | (sccm) | (sec) | (sec) | [Å] | [Å/min] | R.I. | [g/cm³] |
| ALD | 24 | 5 | 500 | 100 | 3 | — | 394 | 2.63 | 1.56 | 2.45 |
| | 24 | 5 | 1000 | 100 | 3 | — | 268 | 2.68 | 1.54 | 2.48 |
| | 24 | 5 | 2000 | 100 | 3 | — | 223 | 2.23 | 1.62 | 2.47 |
| | −1 | 20 | 2000 | — | 10 | — | 395 | 1.98 | 1.59 | 2.26 |
| | −1 | 20 | 2000 | — | 10 | 20 | 188 | 1.88 | 1.74 | 2.65 |
| | 24 | 2 | 1000 | 100 | 3 | — | 403 | 2.01 | 1.5 | 2.33 |
| | 24 | 1 | 1000 | 100 | 3 | — | 328 | 1.64 | 1.5 | 2.27 |
| | 9 | 1 | 1000 | 100 | 3 | — | 258 | 1.29 | 1.51 | 2.25 |
| | 9 | 1 | 1000 | 100 | 3 | 5 | 264 | 1.32 | 1.47 | 2.27 |
| | 9 | 1 | 1000 | 100 | 3 | 10 | 248 | 1.24 | 1.53 | 2.31 |
| | 9 | 1 | 1000 | 100 | 3 | 20 | 256 | 1.28 | 1.49 | 2.27 |
| | 9 | 1 | 2000 | 20 | 3 | 20 | 239 | 1.19 | 1.59 | 2.48 |
| | 9 | 1 | 2000 | 20 | 2 | 20 | 201 | 0.67 | 1.9 | — |
| | 9 | 1 | 2000 | 20 | 1 | 20 | 246 | 0.62 | 1.73 | — |
| | 9 | 1 | 2000 | 50 | 1 | 20 | 253 | 0.63 | 1.74 | — |
| | 9 | 1 | 2000 | 100 | 1 | 20 | 304 | 0.76 | 1.6 | — |
| | 9 | 1 | 2000 | 500 | 1 | 20 | 271 | 0.68 | 1.74 | — |
| | 9 | 1 | 2000 | 1000 | 1 | 20 | 441 | 1.1 | 1.58 | — |

In addition, the composition of the deposited thin film was analyzed using an X-ray photoelectron spectroscope, and the content values for each atom in the deposited thin film depending on the deposition conditions are shown in the following Table 3. It was confirmed that the silicon oxide film was able to be deposited with a high deposition rate, a silicon oxide film containing fluorine was able to be formed, and other compositions of C and N were able to be included under different thin film deposition conditions, by using the trisilylamine compound of the present disclosure as a precursor.

TABLE 3

| | | | | | Reaction | | | | | | | |
|---|---|---|---|---|---|---|---|---|---|---|---|---|
| | Precursor | | Oxygen | Hydrogen | gas | 1-Hexene | | | | | | |
| | | Injection | flow | flow | injection | injection | Composition of film | | | | | |
| | Temperature | time | rate | rate | time | time | (at %) | | | | | |
| Deposition | (° C.) | (sec) | (sccm) | (sccm) | (sec) | (sec) | C | N | O | Si | F | Cl |
| ALD | 24 | 5 | 500 | 100 | 3 | — | 0 | 7.1 | 5.43 | 36.9 | 1.6 | 0 |
| | 24 | 5 | 1000 | 100 | 3 | — | 0 | 3.1 | 59.0 | 36.7 | 1.1 | 0 |
| | 24 | 5 | 2000 | 100 | 3 | — | 0 | 6.3 | 55.2 | 36.9 | 1.5 | 0 |
| | −1 | 20 | 2000 | — | 10 | — | 4.8 | 11.1 | 44.8 | 37.0 | 2.3 | 0 |
| | −1 | 20 | 2000 | — | 10 | 20 | 14.4 | 15.6 | 32.1 | 35.0 | 2.9 | 0 |
| | 24 | 2 | 1000 | 100 | 3 | — | 0 | 0.6 | 65.9 | 32.9 | 0.7 | 0 |
| | 24 | 1 | 1000 | 100 | 3 | — | 0 | 0 | 66.5 | 32.8 | 0.7 | 0 |
| | 9 | 1 | 1000 | 100 | 3 | — | 0 | 0 | 66.7 | 32.7 | 0.6 | 0 |
| | 9 | 1 | 1000 | 100 | 3 | 5 | 0 | 0 | 66.4 | 33.0 | 0.6 | 0 |
| | 9 | 1 | 1000 | 100 | 3 | 10 | 0 | 0 | 66.4 | 33.0 | 0.6 | 0 |
| | 9 | 1 | 1000 | 100 | 3 | 20 | 0 | 0 | 66.4 | 33.0 | 0.6 | 0 |
| | 9 | 1 | 2000 | 20 | 3 | 20 | 0 | 3.8 | 58.7 | 36.6 | 0.9 | 0 |
| | 9 | 1 | 2000 | 20 | 2 | 20 | 11 | 12.2 | 40.4 | 34.5 | 1.8 | 0 |
| | 9 | 1 | 2000 | 20 | 1 | 20 | 22.6 | 14.1 | 27.8 | 33.4 | 2.2 | 0 |
| | 9 | 1 | 2000 | 50 | 1 | 20 | 19.6 | 13.6 | 30.4 | 34.4 | 2.0 | 0 |
| | 9 | 1 | 2000 | 100 | 1 | 20 | 18.3 | 13.2 | 32.5 | 34.0 | 2.0 | 0 |
| | 9 | 1 | 2000 | 500 | 1 | 20 | 14.1 | 12.2 | 37.6 | 37.6 | 1.5 | 0 |
| | 9 | 1 | 2000 | 1000 | 1 | 20 | 0 | 5.0 | 57.6 | 36.8 | 0.7 | 0 |

### [Example 5] 2-Step Thermal Atomic Layer Deposition (2-Step TALD)

A silicon-containing thin film was manufactured in a common thermal atomic layer deposition (TALD) device using atomic layer deposition (ALD). Bis(fluoromethylsilyl)methylsilylamine prepared in Example 1 was used as a precursor, oxygen, hydrogen, and 1-hexene were used as a reaction gas, and argon was used as a purge gas.

A silicon substrate was set to the condition of 630° C., and as shown in the following Table 4, the precursor was maintained at 9° C. after being filled into a stainless steel bubbler container, and 1-hexene was maintained at −20° C. after being filled into a stainless steel bubbler container. First, the precursor vaporized in the stainless steel bubbler container was transferred to a silicon substrate for 1 second using 100 sccm of argon gas as a transfer gas and adsorbed onto the silicon substrate. Second, an unadsorbed precursor was removed for about 10 seconds using 1,000 sccm of argon gas, and third, 1-hexene as a reaction gas was flowed for 10 to 40 seconds using 100 sccm of argon gas as a transfer gas and then unadsorbed reactants were removed for about 10 seconds using 1,000 sccm of argon gas again. Fourth, 2000 sccm of oxygen and 1000 sccm of hydrogen as reaction gases were flowed for about 10 to 40 seconds to form a thin film, and reaction by-products and residual reaction gas were removed for about 10 seconds using 1,000 sccm of argon gas. Finally, 1-hexene was flowed again using 100 sccm of argon gas as a transfer gas for 10 to 40 seconds, and then unadsorbed reactants were removed for about 10 seconds using 1,000 sccm of argon gas. The above-described process was 1 cycle, and a set of cycles was repeated to form a silicon oxide film.

The thin film deposition conditions are shown in the following Table 4, and the detailed deposition conditions, deposition results depending on the deposition conditions, the thickness of the deposited thin film, and refractive index (R.I.) were measured and are shown in the following Table 5.

TABLE 4

| | | Bis(fluoromethylsilyl) |
|---|---|---|
| Precursor | | methylsilylamine |
| Deposition | | 2-Step thermal atomic layer |
| | | deposition (2-step TALD) |
| Substrate temperature (° C.) | | 630 |
| Precursor | heating temperature (° C.) | 9 |
| | Injection time (sec) | 1 |
| | Transfer gas (sccm) | 100 |
| Purge gas | Flow rate (sccm) | 1000 |
| | Time (sec) | 10 |
| Reaction gas | Oxygen flow rate (sccm) | 2000 |
| | Hydrogen flow rate | 1000 |
| | (sccm) | |
| | Injection time (sec) | 1 |
| 1-Hexene | heating temperature (° C.) | −20 |
| | Injection time (sec) | 10-40 |
| | Transfer gas (sccm) | 100 |
| Purge gas | flow rate (sccm) | 1000 |
| | Time (sec) | 10 |
| Number of | cycle | 400 |
| deposition | | |

TABLE 5

| | | | | | | Reaction | Second | | | |
|---|---|---|---|---|---|---|---|---|---|---|
| | Silicon precursor | | First | Oxygen | Hydrogen | gas | 1-hexene | | | |
| | | Injection | 1-hexene | flow | flow | injection | injection | Film | Growth | |
| | Temperature | Time | injection | rate | rate | time | time | thickness | rate | |
| Deposition | (° C.) | (sec) | time (sec) | (sccm) | (sccm) | (sec) | (sec) | [Å] | [Å/min] | RI |
| ALD | 9 | 1 | 10 | 2000 | 1000 | 1 | 10 | 521 | 1.3 | 1.50 |
| | 9 | 1 | 20 | 2000 | 1000 | 1 | 20 | 515 | 1.29 | 1.50 |
| | 9 | 1 | 40 | 2000 | 1000 | 1 | 40 | 380 | 1.27 | 1.53 |

In addition, the composition of the deposited thin film was analyzed using an X-ray photoelectron spectroscope, and the content values for each atom in the deposited thin film depending on the deposition conditions are shown in the following Table 6. It was found that the silicon oxide film may be deposited with a high deposition rate by using the trisilylamine compound of the present disclosure as a precursor, and it was confirmed that the silicon oxide film contained fluorine.

TABLE 6

| | | | First | | | Reaction | Second | | | | | | |
|---|---|---|---|---|---|---|---|---|---|---|---|---|---|
| | Silicon precursor | | 1-hexene | Oxygen | Hydrogen | gas | 1-hexene | | | | | | |
| | | Injection | injection | flow | flow | Injection | injection | Composition of film | | | | | |
| | Temperature | time | time | rate | rate | time | time | (at %) | | | | | |
| Deposition | (° C.) | (sec) | (sec) | (sccm) | (sccm) | (sec) | (sec) | C | N | O | Si | F | Cl |
| ALD | 9 | 1 | 10 | 2000 | 1000 | 1 | 10 | 0 | 2.4 | 60.5 | 36.5 | 0.6 | 0 |
| | 9 | 1 | 20 | 2000 | 1000 | 1 | 20 | 0 | 2.9 | 59.6 | 37.0 | 0.5 | 0 |
| | 9 | 1 | 40 | 2000 | 1000 | 1 | 40 | 0 | 3.2 | 59.1 | 37.1 | 0.5 | 0 |

The trisilylamine compound according to an embodiment of the present disclosure has excellent thermal stability, allows deposition of a thin film with a high thin film deposition rate even under a low temperature condition, and allows manufacture of a high-quality silicon-containing thin film with high purity by a simple manufacturing process.

In addition, since the silicon-containing thin film manufactured from the trisilylamine compound according to an embodiment has both excellent chemical and thermal stability and also has low permittivity, it is expected to be usefully applied as an insulating film of a semiconductor device, in particular, a spacer of a semiconductor miniaturization process.

Hereinabove, although the present disclosure has been described by specific matters, Examples, and Comparative Examples, they have been provided only for assisting in the entire understanding of the present disclosure. Therefore, the present disclosure is not limited to the above Examples. Various modifications and changes may be made by those skilled in the art to which the present disclosure pertains from this description.

Therefore, the spirit of the present disclosure should not be limited to the above-described exemplary embodiments, and the following claims as well as all modifications equal or equivalent to the claims are intended to fall within the scope and spirit of the disclosure.

What is claimed is:

1. A trisilylamine compound represented by the following Chemical Formula 1: 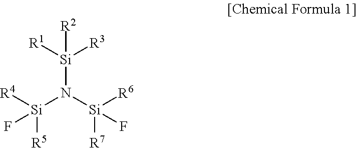
wherein
R¹ to R⁷ are independently of one another hydrogen, C1-C7 alkyl, or fluoro.

2. The trisilylamine compound of claim 1,
wherein R¹, R⁴, and R⁶ are independently of one another hydrogen or fluoro; and
R², R³, R⁵, and R⁷ are independently of one another hydrogen, C1-C7 alkyl, or fluoro.

3. The trisilylamine compound of claim 1, wherein the trisilylamine compound is represented by the following Chemical Formula 2: 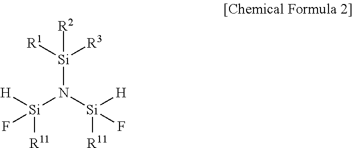
wherein
R¹ to R³ and R¹¹ are independently of one another hydrogen, C1-C7 alkyl, or fluoro.

4. The trisilylamine compound of claim 3,
wherein R¹ is hydrogen or fluoro;
R² and R³ are independently of each other hydrogen, C1-C7 alkyl, or fluoro; and
R¹¹ is C1-C7 alkyl or fluoro.

5. The trisilylamine compound of claim 1, wherein the trisilylamine compound is selected from the following structures:

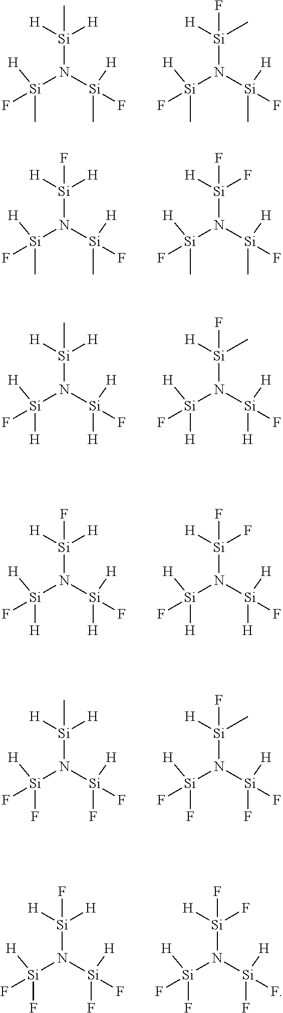

6. A composition for depositing a silicon-containing thin film comprising the trisilylamine compound of claim 1.

7. A silicon-containing thin film manufactured from a trisilylamine compound represented by the following Chemical Formula 1 or a composition for depositing a thin film comprising the compound: 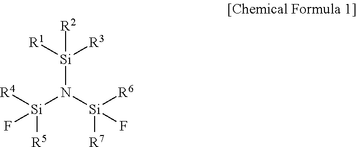
wherein
R¹ to R⁷ are independently of one another hydrogen, C1-C7 alkyl, or fluoro.

8. A method of manufacturing a silicon-containing thin film, which uses a trisilylamine compound represented by the following Chemical Formula 1 or a composition for depositing a thin film comprising the compound; and a reaction gas: 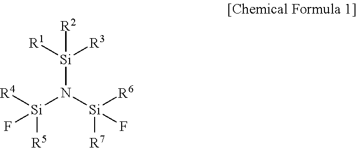
wherein
R¹ to R⁷ are independently of one another hydrogen, C1-C7 alkyl, or fluoro.

9. The method of manufacturing a silicon-containing thin film of claim 8, wherein the reaction gas comprises oxygen (O₂), ozone (O₃), oxygen plasma, hydrogen (H₂), hydrogen plasma, water (H₂O), hydrogen peroxide (H₂O₂), nitrogen (NO₂), nitrogen monoxide (NO), nitrous oxide (N₂O), ammonia (NH₃), carbon dioxide (CO₂), formic acid (HCOOH), acetic acid (CH₃COOH), anhydrous acetic acid ((CH₃CO)₂O), or a combination thereof.

10. The method of manufacturing a silicon-containing thin film of claim 9, wherein the reaction gas further comprises a hydrocarbon gas.
